(19) United States
(12) Patent Application Publication
(10) Pub. No.: US 2025/0051920 A1
(43) Pub. Date: Feb. 13, 2025

(54) SUBSTRATE-PROCESSING APPARATUS AND SUBSTRATE-PROCESSING METHOD

(71) Applicant: Tokyo Electron Limited, Tokyo (JP)

(72) Inventors: Yudai FUKUSHI, Iwate (JP); Junnosuke TAGUCHI, Iwate (JP); Yasushi TAKEUCHI, Iwate (JP); Takehiro FUKADA, Iwate (JP)

(21) Appl. No.: 18/788,436

(22) Filed: Jul. 30, 2024

(30) Foreign Application Priority Data
Aug. 7, 2023 (JP) 2023-128760

(51) Int. Cl. C23C 16/458; C23C 16/455; C23C 16/52; H01L 21/67

(52) U.S. Cl. CPC C23C 16/4584; C23C 16/45544; C23C 16/52; H01L 21/67017

(57) ABSTRACT

A substrate-processing apparatus includes a process chamber configured to process a plurality of substrates; a rotation table that is disposed in an interior of the process chamber so as to be rotatable and at which the substrates are to be placed at positions that are away in a radial direction of the rotation table from a center of rotation of the rotation table; a supply member configured to supply gas to the substrates placed on the rotation table; and a raising and lowering mechanism configured to raise and lower the supply member relative to the rotation table.

### CROSS-REFERENCE TO RELATED APPLICATIONS

This application is based upon and claims priority to Japanese Patent Application No. 2023-128760, filed on Aug. 7, 2023, the entire contents of which are incorporated herein by reference.

### BACKGROUND

### 1. Field of the Invention

The present disclosure relates to substrate-processing apparatuses and substrate-processing methods.

### 2. Description of the Related Art

Substrate-processing apparatuses are configured to heat a substrate housed in a process chamber, and supply processing gases to the substrate, thereby performing processes of the substrate, such as a film-forming process, an etching process, and the like. In such substrate-processing apparatuses of this type, the process chamber is at a high temperature before the substrate is housed. Thus, the substrate housed in the process chamber may warp due to the high temperature of the process chamber, and may interfere with the components in the process chamber, such as a supply member configured to supply gas.

Japanese Patent Application Publication No. 2019-16662 discloses a substrate-processing apparatus including a substrate warpage-monitoring device configured to detect warpage of a substrate placed on a rotation table in a process chamber. According to this substrate-processing apparatus, the substrate warpage-monitoring device monitors warpage of the substrate and controls the rotation speed, stop of rotation, and the like of the rotation table.

### SUMMARY

According to an aspect of the present disclosure, a substrate-processing apparatus includes: a process chamber configured to process a plurality of substrates; a rotation table that is disposed in an interior of the process chamber so as to be rotatable and at which the substrates are to be placed at positions that are away in a radial direction of the rotation table from a center of rotation of the rotation table; a supply member configured to supply gas to the substrates placed on the rotation table; and a raising and lowering mechanism configured to raise and lower the supply member relative to the rotation table.

### BRIEF DESCRIPTION OF THE DRAWINGS

FIG. 1 is a vertical cross-sectional view illustrating a configuration example of a substrate-processing apparatus according to an embodiment of the present disclosure;

FIG. 2 is a plan view illustrating the configuration of the interior of a process chamber of the substrate-processing apparatus of FIG. 1;

FIG. 3 is a perspective view illustrating the configuration of a rotation table and stages of the substrate-processing apparatus of FIG. 1;

FIG. 4 is a cross-sectional view schematically illustrating the configuration of a raw material gas supply of the substrate-processing apparatus;

FIG. 5 is a perspective view illustrating components of a raising and lowering mechanism provided externally of the process chamber;

FIG. 6A is an explanatory view illustrating adjustment of a vertical position of a shower head performed by a driver, and illustrates a raised position of the shower head;

FIG. 6B is an explanatory view illustrating adjustment of a vertical position of a shower head performed by a driver, and illustrates a processing position of the shower head;

FIG. 7 is a flowchart illustrating a substrate-processing method performed by the substrate-processing apparatus;

FIG. 8 is a cross-sectional side view illustrating a raising and lowering mechanism according to a first modified example;

FIG. 9A is a cross-sectional side view illustrating a raising and lowering mechanism according to a second modified example; and

FIG. 9B is a cross-sectional side view illustrating a raising and lowering mechanism according to a third modified example.

### DETAILED DESCRIPTION OF THE INVENTION

The present disclosure provides a technique of being able to avoid interference between a substrate and a supply member configured to supply gas, and perform processing of the substrate with high accuracy.

Hereinafter, embodiments of the present disclosure will be described with reference to the drawings. In the drawings, the same components are denoted by the same reference symbols, and duplicate description thereof may be omitted.

### [Configuration of Substrate-Processing Apparatus 1]

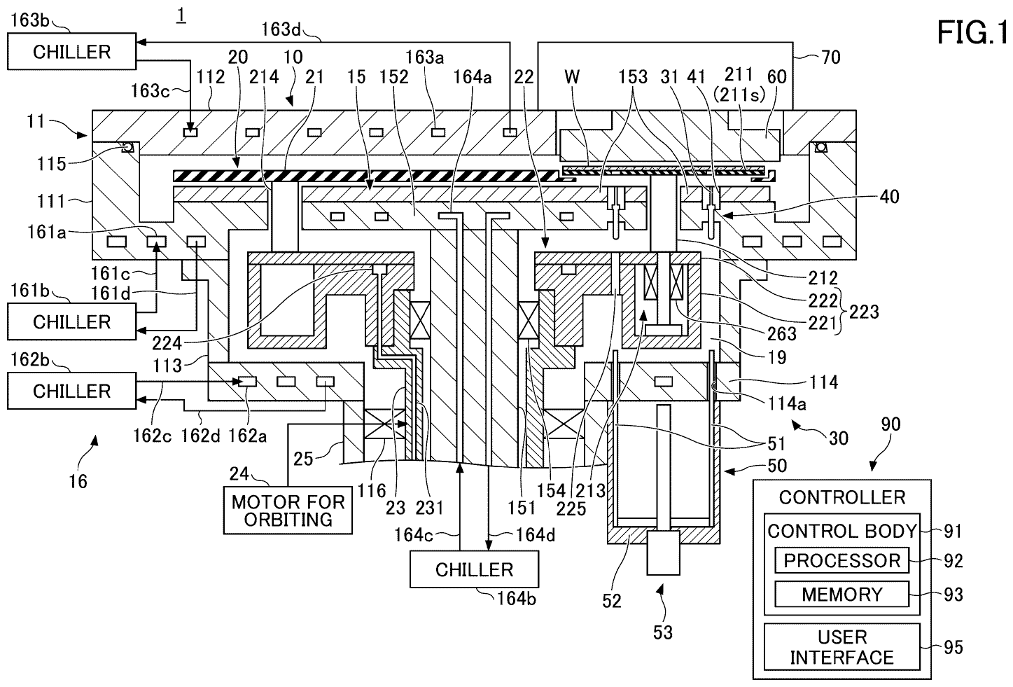

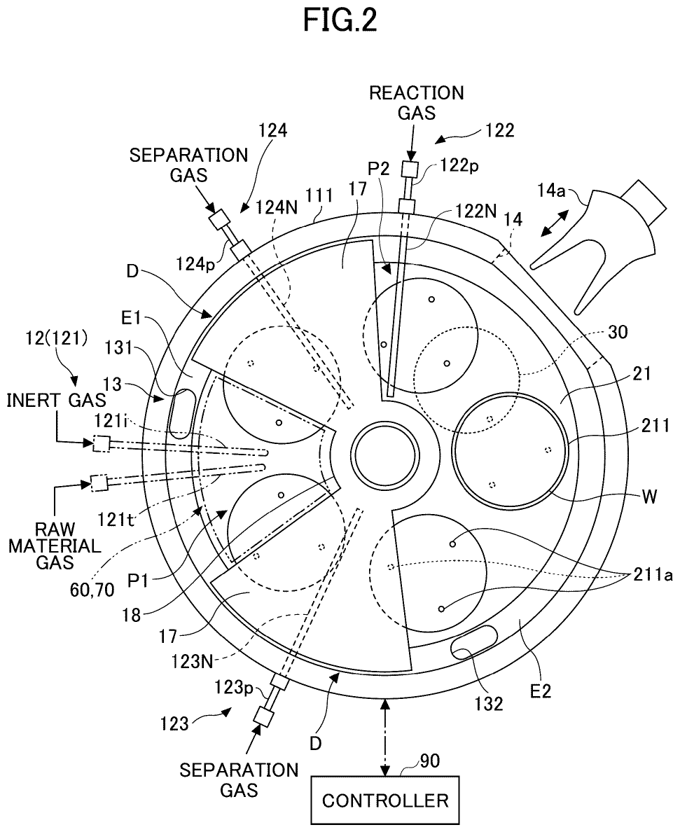

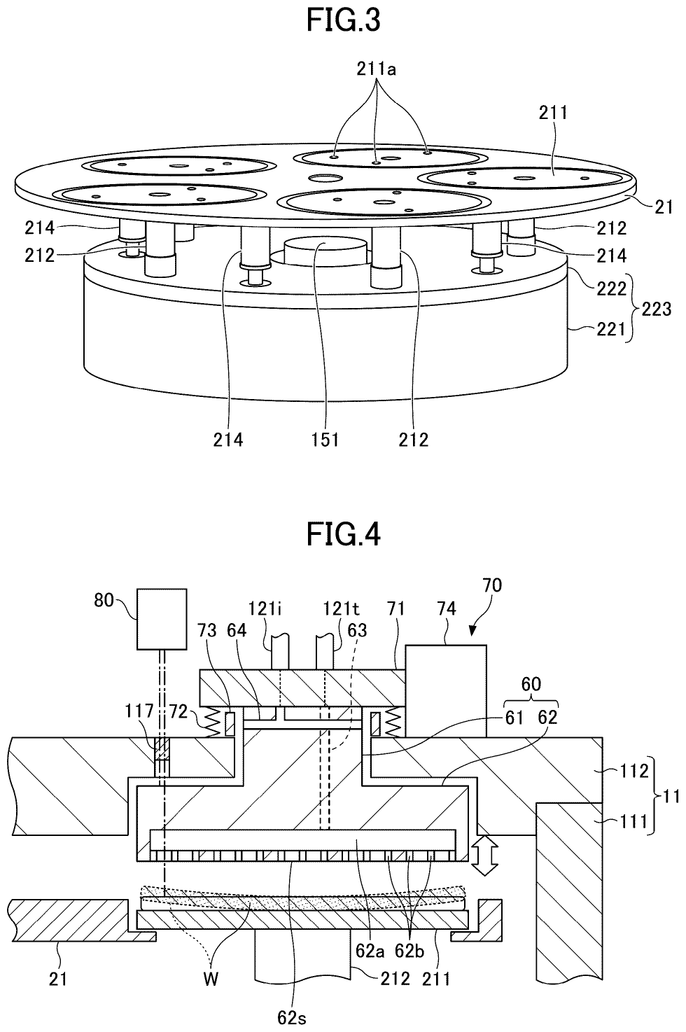

A substrate-processing apparatus 1 according to an embodiment of the present disclosure will be described with reference to FIGS. 1 to 3. FIG. 1 is a vertical cross-sectional view illustrating a configuration example of the substrate-processing apparatus 1 according to the embodiment. FIG. 2 is a plan view illustrating the configuration of the interior of a process chamber 11 of the substrate-processing apparatus 1 of FIG. 1. In FIG. 2, for the sake of convenience, illustration of a top plate 112 of the process chamber 11 is omitted. FIG. 3 is a perspective view illustrating the configuration of a rotation table 21 and stages 211 of the substrate-processing apparatus 1 of FIG. 1.

The substrate-processing apparatus 1 is configured to perform, as the processing of the substrate, a film-forming process for forming a film on the surface of a substrate W through atomic layer deposition (ALD) or molecular layer deposition (MLD). The processing of the substrate performed by the substrate-processing apparatus 1 is not limited to the film-forming process, and may be an etching process, a cleaning process, or the like. Specifically, the substrate-processing apparatus 1 includes a processor 10, a rotation driver 20, a lifter 30, and a controller 90.

The processor 10 is configured to perform a film-forming process for forming a film on the substrate W. The processor 10 includes a process chamber 11, a gas introducer 12, a gas exhauster 13, a transfer port 14, a heater 15, and a cooler 16.

The process chamber 11 is a vacuum chamber configured such that the internal space thereof can be reduced in pressure to a vacuum atmosphere. The process chamber 11 is formed as a flat casing having a generally circular planar shape, and can house a plurality of substrates W in the internal space thereof. The substrate W may be, for example, a semiconductor wafer. The process chamber 11 includes a body 111, a top plate 112, a side wall 113, and a bottom plate 114 (FIG. 1). The body 111 has a cylindrical shape. The top plate 112 is detachably attached to the upper surface of the body 111. The body 111 and the top plate 112 hermetically contact each other by means of a sealing 115. The side wall 113 has a cylindrical shape, and is hermetically connected to the lower surface of the body 111. The bottom plate 114 is hermetically connected to the bottom surface of the side wall 113.

The gas introducer 12 includes a raw material gas supply 121, a reaction gas supply 122, and separation gas supplies 123 and 124 (FIG. 2). The raw material gas supply 121, the reaction gas supply 122, and the separation gas supplies 123 and 124 are disposed above the rotation table 21 described below so as to be apart from each other in the circumferential direction of the process chamber 11. In the illustrated example, the separation gas supply 123, the raw material gas supply 121, the separation gas supply 124, and the reaction gas supply 122 are arranged in this order clockwise (rotating direction of the rotation table 21) from the transfer port 14.

The raw material gas supply 121 is configured to supply a raw material gas to the process chamber 11. The raw material gas supply 121 according to the embodiment includes: a shower head 60 covering a set circumferential range in the process chamber 11; and a raw material gas supply tube 121t and an inert gas supply tube 121i that extend outward of the process chamber 11 and are connected to the shower head 60.

The raw material gas supply tube 121t is connected to a raw material gas supply path externally of the process chamber 11. The raw material gas supply path includes an unillustrated flow rate regulator, an unillustrated valve, and the like at a location partway thereof, and is connected to an unillustrated supply source configured to supply the raw material gas. As the raw material gas, a silicon-containing gas, a metal-containing gas, or the like can be used. The raw material gas supply 121 supplies the raw material gas to the shower head 60 through the raw material gas supply tube 121t, and discharges the raw material gas from the shower head 60 to the internal space of the process chamber 11. The lower region of the shower head 60 serves as a raw material gas processing region P1 in which the raw material gas is adsorbed on the substrate W.

The inert gas supply tube 121i is connected to an inert gas supply path externally of the process chamber 11. The inert gas supply path also includes an unillustrated flow rate regulator, an unillustrated valve, and the like at a location partway thereof, and is connected to an unillustrated supply source configured to supply the inert gas. As the inert gas, a nitrogen (N₂) gas, an argon (Ar) gas, or the like can be used. The raw material gas supply 121 supplies the inert gas to the shower head 60 through the inert gas supply tube 121i, and discharges the inert gas to the internal space of the process chamber 11 from a position different from a position from which the raw material gas is supplied from the shower head 60. The configuration of the shower head 60 will be described in detail below.

The reactive gas supply 122 supplies a reactive gas to the process chamber 11. The reactive gas supply 122 according to the embodiment includes a reactive gas nozzle 122N extending in the radial direction of the process chamber 11. The reactive gas nozzle 122N is fixed to the side wall of the body 111, and includes a gas introduction port 122p projecting outward of the body 111. The reactive gas nozzle 122N is formed of quartz or the like, and disposed in the process chamber 11 so as to be parallel to the rotation table 21.

The reaction gas nozzle 122N is connected to a reaction gas supply path externally of the process chamber 11. The reaction gas supply path includes an unillustrated flow rate regulator, an unillustrated valve, and the like at a location partway thereof, and is connected to an unillustrated supply source configured to supply the reaction gas. As the reaction gas, an oxidizing gas, a nitriding gas, or the like can be used. The reaction gas nozzle 122N is provided with a plurality of unillustrated discharge holes that are open toward the rotation table 21 and are arranged so as to be apart from each other along the axial direction of the reaction gas nozzle 122N. The lower region of the reaction gas nozzle 122N serves as a reaction gas processing region P2 in which oxidizing or nitriding of the raw material gas adsorbed on the substrate W is performed. In the embodiment, the processing gas for processing the substrate W corresponds to the raw material gas and the reaction gas as described above.

The separation gas supplies 123 and 124 are configured to supply the separation gas to the process chamber 11. The separation gas supplies 123 and 124 according to the embodiment are provided with separation gas nozzles 123N and 124N extending in the radial direction of the process chamber 11. The separation gas nozzles 123N and 124N are fixed to the side wall of the body 111, and include gas introduction ports 123p and 124p projecting outward of the body. The separation gas nozzles 123N and 124N are formed of quartz or the like, and are arranged in the process chamber 11 so as to be parallel to the rotation table 21.

The separation gas nozzles 123N and 124N are connected to separation gas supply paths externally of the process chamber 11. The separation gas supply paths each include an unillustrated flow rate regulator, an unillustrated valve, and the like at a location partway thereof, and is connected to an unillustrated supply source configured to supply the separation gas. As the separation gas, an inert gas, such as an argon (Ar) gas, a nitrogen (N₂) gas, or the like can be used. The separation gas nozzles 123N and 124N are each provided with a plurality of unillustrated discharge holes that are open toward the rotation table 21 and are arranged so as to be apart from each other along the axial direction of each of the separation gas nozzles 123N and 124N.

As illustrated in FIG. 2, two projections 17 are provided in the process chamber 11. In order to form separation regions D together with the separation gas nozzles 123N and 124N, the projections 17 are attached to the back surface of the top plate 112 so as to project toward the rotation table 21. The projections 17 each have a fan-like planar shape in which the top thereof is cut into an arc shape, and are disposed such that the inner arc thereof is connected to an annular projection 18, and the outer arc thereof is disposed along the side wall of the process chamber 11.

The gas exhauster 13 includes a first gas exhaustion port 131 and a second gas exhaustion port 132 (FIG. 2). The first gas exhaustion port 131 is formed in the bottom of a first gas exhaustion region E1 communicating with the raw material gas processing region P1. The second gas exhaustion port 132 is formed in the bottom of a second gas exhaustion region E2 communicating with the reaction gas processing region P2. The first gas exhaustion port 131 and the second gas exhaustion port 132 are connected to an unillustrated gas exhaustion device through an unillustrated gas exhaustion tube.

The transfer port 14 is provided in the side wall of the body 111 (FIG. 2). Through the transfer port 14, transfer of the substrate W is performed between the rotation table 21 in the process chamber 11 and a transfer device 14a located externally of the process chamber 11. The transfer port 14 is opened and closed by an illustrated gate valve.

The heater 15 includes a fixed shaft 151, a heater support 152, and a heat generator 153 (FIG. 1).

The fixed shaft 151 has a cylindrical shape having the center of the process chamber 11 as the center axis. The fixed shaft 151 penetrates the bottom plate 114 of the process chamber 11 internally of a rotation shaft 23 of the rotation driver 20 described below.

The heater support 152 is fixed to the top of the fixed shaft 151 and has a disk shape. The heater support 152 is configured to support the heat generator 153.

The heat generator 153 is provided on the upper surface of the heater support 152. The heat generator 153 may be provided on the body 111 in addition to the upper surface of the heater support 152. The heat generator 153 is configured to generate heat when power is supplied from an unillustrated power supply, thereby heating the substrate W. Also, the heat generator 153 may include a shielding plate on the upper surface (the surface facing the rotation table 21). The shielding plate is configured to prevent exposure of the heat generator 153 to the processing gas.

The cooler 16 includes fluid flow paths 161a to 164a, chillers 161b to 164b, inlet tubes 161c to 164c, and outlet tubes 161d to 164d (FIG. 1). The fluid flow paths 161a to 164a are formed in the body 111, the top plate 112, the bottom plate 114, and the heater support 152. The chillers 161b to 164b output temperature-controlled fluids. The temperature-controlled fluids output from the chillers 161b to 164b flow and circulate through the inlet tubes 161c to 164c, the fluid flow paths 161a to 164a, and the outlet tubes 161d to 164d in this order. This adjusts the temperatures of the body 111, the top plate 112, the bottom plate 114, and the heater support 152. As the temperature-controlled fluid, a fluorine-based fluid, such as GALDEN (registered trademark) or the like, or water can be used.

The rotation driver 20 includes the rotation table 21, a housing box 22, the rotation shaft 23, a motor for orbiting 24, and a cylinder 25.

The rotation table 21 is provided in the process chamber 11, and has the center of rotation at the center of the process chamber 11. The rotation table 21 has a disk shape or the like, and is formed of quartz. A plurality of (e.g., five) stages 211 are provided at the upper surface of the rotation table 21 along the rotating direction (circumferential direction). The rotation table 21 is connected to the housing box 22 via a plurality of connectors 214 (FIG. 3).

The stages 211 each have a disk shape that is slightly larger than the substrate W, and is formed of quartz or the like. A stage surface 211s on which the substrate W is to be placed is formed on the upper surface of each of the stages 211. The stages 211 are each connected to a motor for spinning 213 via a spinning shaft 212 and configured to be rotatable with respect to the rotation table 21 (FIG. 1).

The spinning shaft 212 connects the lower surface of the stage 211 to the motor for spinning 213 housed in the housing box 22, and transmits a driving force of the motor for spinning 213 to the stage 211. The spinning shaft 212 is configured to be rotatable about the center of the stage 211. The spinning shaft 212 is provided to penetrate a ceiling 222 of the housing box 22 and the rotation table 21. A sealing 263 is provided near a place in which the spinning shaft 212 penetrates the ceiling 222 of the housing box 22, thereby maintaining a hermetical state of the housing box 22. The sealing 263 includes a magnetic fluid sealing or the like.

The motor for spinning 213 spins the substrate W about the center of the substrate W by rotating the stage 211 relative to the rotation table 21 via the spinning shaft 212. The motor for spinning 213 is preferably a servo motor or the like.

The connectors 214 each connect the lower surface of the rotation table 21 and the upper surface of the housing box 22 (FIG. 3). The connectors 214 are provided along the circumferential direction of the rotation table 21.

The housing box 22 is provided below the rotation table 21 in the process chamber 11. The housing box 22 is connected to the rotation table 21 via the connectors 214, and rotates integrally with the rotation table 21. The housing box 22 may be configured to be movable upward and downward in the process chamber 11 by an unillustrated raising and lowering mechanism. The housing box 22 includes a body 221 and a ceiling 222.

The body 221 is formed in a recessed shape in a longitudinal cross-sectional view, and is formed in a ring shape along the rotating direction of the rotation table 21 (FIG. 1).

The ceiling 222 is provided on the upper surface of the body 221 so as to cover the opening of the body 221. Thereby, the body 221 and the ceiling 222 form a rotation housing 223 isolated from the interior of the process chamber 11.

The rotation housing 223 is formed in a rectangular shape in a longitudinal cross-sectional view, and has a ring shape along the rotating direction of the rotation table 21. The rotation housing 223 houses a motor for spinning 213 (source of rotation). The body 221 is provided with a communication path 224 through which the rotation housing 223 is communicated with the exterior of the substrate-processing apparatus 1. Thereby, air is introduced into the rotation housing 223 from the exterior of the substrate-processing apparatus 1, and the interior of the rotation housing 223 is cooled and maintained at the atmospheric pressure. In order to dispose this rotation housing 223 so as to be rotatable, the process chamber 11 includes a rotation source housing space 19 enclosed by a side wall 113, a bottom plate 114, and a heater 15.

The rotation shaft 23 is fixed to the lower part of the housing box 22. The rotation shaft 23 is provided to penetrate the bottom plate 114 of the process chamber 11. The rotation shaft 23 transmits a driving force of the motor for orbiting 24 to the rotation table 21 and the housing box 22, and integrally rotates the rotation table 21 and the housing box 22. A sealing 154 is provided between the outer wall of the fixed shaft 151 and the inner wall of the rotation shaft 23 of the rotation driver 20. Thereby, the rotation shaft 23 rotates with respect to the fixed shaft 151 while maintaining a hermetical state of the interior of the process chamber 11. A magnetic fluid sealing or the like can be applied to the sealing 154.

The cylinder 25 of the rotation driver 20 is connected to the bottom plate 114 of the process chamber 11 at the lower surface thereof that is closer to the center thereof. The cylinder 25 supports the process chamber 11 together with the fixed shaft 151 of the process chamber 11. A sealing 116 is provided between the rotation shaft 23 and the cylinder 25, thereby maintaining a hermetical state of the interior of the process chamber 11. A magnetic fluid sealing or the like can be applied to the sealing 116.

A flow path 231 is formed in the rotation shaft 23. The flow path 231 is connected to the communication path 224 of the housing box 22, and functions as a fluid flow path through which air is introduced into the housing box 22. The flow path 231 also functions as a wiring duct through which power lines and signal lines for driving the motor for spinning 213 are introduced into the housing box 22. For example, the flow path 231 is provided in the same number as the number of the motors for spinning 213.

As illustrated in FIG. 1, when the transfer device 14a (FIG. 2) transfers the substrate W into and out of the stage 211, the lifter 30 raises and lowers a plurality of (three in this embodiment) the lift pins 31, thereby performing delivery of the substrate W between the transfer device 14a and the stage 211. The substrate-processing apparatus 1 includes the lifter 30 on the lower side in the vertical direction at a position facing the stage next to the transfer port 14. The lifter 30 includes, in the process chamber 11, a plurality of (three) upper structures 40 each having a plurality of lift pins 31, and one lower mover 50 configured to raise or lower the lift pins 31 at the same time.

The upper structures 40 are each disposed so as to penetrate the heater support 152 and the heat generator 153, and houses the lift pins 31 so as to be displaceable. The lower mover 50 is attached to the lower surface of the bottom plate 114 of the process chamber 11. The lower mover 50 includes a plurality of (three) plungers 51 configured to be displaced along the vertical direction and press the lower ends of the lift pins 31. That is, the lifter 30 has a two-step structure including two moving members: the lift pins 31 configured to contact the substrate W; and the plungers 51 configured to indirectly raise and lower the substrate W via the lift pins 31, with the lift pins 31 and the plungers 51 being separated in the vertical direction.

The lower mover 50 includes a casing 52 and a plunger driver 53 in addition to the plungers 51. The plungers 51 are each formed as a thin and long solid rod, and move in the rotation source housing space 19 by the plunger driver 53. The lifter 30 contacts the lift pins 31 of the upper structure 40 in response to rising of the plunger 51, thereby pushing up the lift pins 31.

The upper structures 40 are provided to be apart from the spinning shaft 212 in the radial direction and to be along the circumferential direction of the stage 211. The upper structures 40 support the lift pins 31 on the lower side in the vertical direction such that the lift pins 31 are not removable. Also, at the positions at which the upper structures 40 are disposed, the stage 211 has a plurality of (three) through-holes 211a through which the lift pins 31 can pass (see also FIG. 2). The lift pins 31 are cylindrical members that extend in the form of a straight line, and rise by the lower ends thereof being pushed up by the plungers 51 that are rising. Thereby, the upper ends of the lift pins 31 project beyond the upper surface of the stage 211 through the through-holes 211a of the stage 211.

According to the substrate-processing apparatus 1 configured as described above, the substrate W is transferred directly above the stage 211 through the transfer port 14, and the substrate W is placed on the stage surface 211s of the stage 211 through rising or lowering of the lift pins 31 of the lifter 30. The interior of the process chamber 11 is heated by the heater 15 before transfer of the substrate W. Therefore, the substrate W placed on the stage 211 of the process chamber 11 may warp by the effect of heat (see the dotted line in FIG. 4).

The warpage of the substrate W is caused by local application of heat to a semiconductor wafer, such as a silicon wafer or the like. Also, the substrate W is deformed so as to have symmetrical warpage across two straight lines that extend in the radial direction and are orthogonal to each other (e.g., a recessed shape in which the outer regions warp upward in the vertical direction compared to the center region). This is because the Young's modulus, Poisson's ratio, and shear modulus of the semiconductor wafer are changed at 90 degrees (°) cycles. However, the warpage of the substrate W in the process chamber 11 is gradually overcome as the temperature increases as a whole over time, and the substrate W returns to the flat shape.

Here, in the raw material gas processing region P1 in which the raw material gas is supplied to the substrate W, it is preferable to dispose a discharge surface 62s of the shower head 60 at a position sufficiently close to the substrate W, and discharge the raw material gas thereto. Thereby, the raw material gas can be applied to the substrate W before the raw material gas widely spreads in the internal space of the process chamber 11. This can uniformly and stably apply the raw material gas to the surface of the substrate W. However, if the substrate W transferred into the process chamber 11 is warped as described above, the substrate W rotated by the rotation table 21 may interfere with the shower head 60 disposed at a position close to the substrate W.

Therefore, the substrate-processing apparatus 1 according to the embodiment includes a raising and lowering mechanism 70 configured to raise and lower the shower head 60 of the raw material gas supply 121 relative to the process chamber 11. The raising and lowering mechanism 70 can avoid interference between the warped substrate W and the shower head 60 by raising the shower head 60 upon transfer of the substrate W. Next, the configurations of the shower head 60 of the raw material gas supply 121 and the raising and lowering mechanism 70 will be described with reference to FIG. 4. FIG. 4 is a cross-sectional view schematically illustrating the configuration of the raw material gas supply 121 of the substrate-processing apparatus 1.

The shower head 60 is a supply member that is disposed in a disposition space formed in the top plate 112 of the process chamber 11 and is configured to supply the raw material gas to the internal space of the process chamber 11. The shower head 60 includes an upper connector 61 and a lower discharger 62 that is continuous with the lower portion of the upper connector 61. The lower discharger 62 includes the discharge surface 62s, facing the rotation table 21, on the lower side in the vertical direction. The shower head 60 is formed of a transparent material, such as quartz or the like. Although FIG. 4 illustrates the configuration in which the upper connector 61 and the lower discharger 62 are monolithically formed, the shower head 60 may be formed by assembling a plurality of members.

The upper connector 61 is a structure configured to support the lower discharger 62 and circulate the raw material gas to the lower discharger 62. For example, the upper connector 61 is formed into a column having a regular circular shape in a cross-sectional plan view. The upper end of the upper connector 61 is connected to the raising and lowering mechanism 70. In order to reduce the weight of the shower head 60, the upper connector 61 may be formed as a cylinder having an inner space.

The lower discharger 62 is configured to disperse and discharge the raw material gas to the substrate W in the process chamber 11. The lower discharger 62 is formed in a fan shape (arc shape) in a cross-sectional plan view. The area of the outer shape of the lower discharger 62 in a plan view is larger than the area of the outer shape of the upper connector 61 in a plan view. A gas diffusion chamber 62a configured to temporarily store the raw material gas and diffuse the raw material gas in the horizontal direction is provided in the lower discharger 62. The lower discharger 62 has a plurality of discharge holes 62b that are formed to penetrate the wall having the discharge surface 62s and communicates with the gas diffusion chamber 62a. Thereby, the discharge holes 62b can continuously discharge the raw material gas diffused in the gas diffusion chamber 62a toward the rotation table 21 located below.

Further, the interior of the shower head 60 includes: a raw material gas flow path 63 that extends from the upper end of the upper connector 61 to the gas diffusion chamber 62a; and an inert gas flow path 64 that extends from the upper end of the upper connector 61 to a location partway of the upper connector 61 and is branched to a plurality of flow paths that extend radially.

The raw material gas flow path 63 communicates with the flow path of the raw material gas supply tube 121t via a connecting block 71 of the raising and lowering mechanism 70 described below. The raw material gas flow path 63 circulates the raw material gas, supplied from the raw material gas supply tube 121t, to the gas diffusion chamber 62a.

The inert gas flow path 64 communicates with the flow path of the inert gas supply tube 121i via the connecting block 71 of the raising and lowering mechanism 70. The radially extending portions of the inert gas flow path 64 communicate with openings formed in the side surfaces of the upper connector 61. Thereby, the inert gas flow path 64 jets the inert gas, supplied from the inert gas supply tube 121i, laterally of the upper connector 61. The inert gas jetted laterally of the upper connector 61 fills the inner space of a bellows 72 of the raising and lowering mechanism 70 described below and the disposition space formed in the top plate 112, thereby suppressing the raw material gas from flowing into these spaces.

Meanwhile, the raising and lowering mechanism 70 configured to raise and lower the shower head 60 includes the connecting block 71, the bellows 72, a shielding plate 73, a driver 74, and a displacement sensor 80.

The connecting block 71 supports and suspends the upper connector 61 of the shower head 60. The connecting block 71 is supported by the driver 74, and moves in the vertical direction under the operation of the driver 74. The area of the outer shape of the connecting block 71 in a plan view is smaller than the area of the outer shape of the lower discharger 62 of the shower head 60 in a plan view. Thereby, the region of the raising and lowering mechanism 70 that receives the atmospheric pressure is reduced, and the load applied when the raising and lowering mechanism 70 raises and lowers the shower head 60 can be reduced.

The bellows 72 is a bellow-like member configured to close the internal space of the process chamber 11 while enabling the shower head 60 to be raised and lowered. For example, the upper end of the bellows 72 is hermetically joined to the lower surface of the connecting block 71, and the lower end of the bellows 72 is hermetically joined to the upper surface of the top plate 112.

The shielding plate 73 is formed into an annular shape in a plan view, and is provided at a position facing the opening of the inert gas flow path 64 of the shower head 60. The shielding plate 73 prevents the inert gas, jetted from the opening of the inert gas flow path 64, from directly contacting the bellows 72, and guides the inert gas in the circumferential direction.

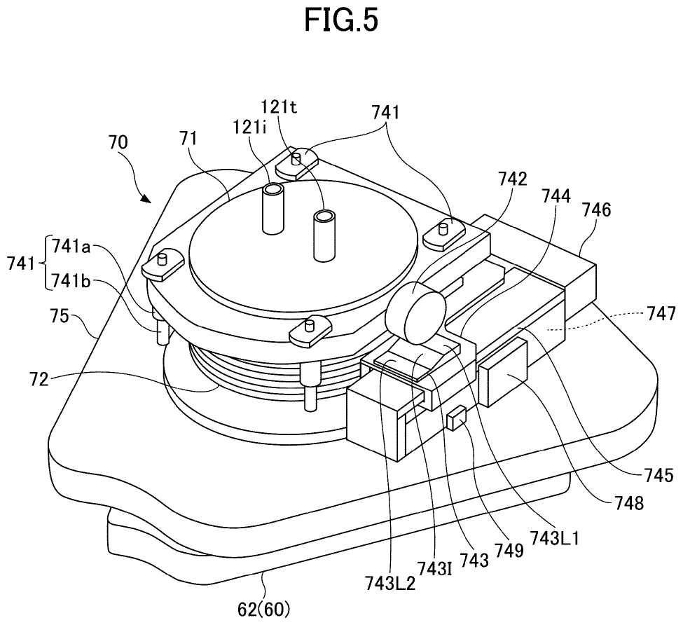

FIG. 5 is a perspective view illustrating the components of the raising and lowering mechanism 70 provided externally of the process chamber 11. In FIG. 5, for ease of understanding, illustration of the top plate 112 of the process chamber 11 is omitted. As illustrated in FIG. 5, the driver 74 of the raising and lowering mechanism 70 is disposed on a fan-shaped (arc-shaped) attachment board 75 that is fixed to the upper surface of the top plate 112 (see FIG. 4). The driver 74 includes a plurality of guides 741, a cam follower 742, a plate cam 743, a slider 744, a rail 745, a drive motor 746, a power transmitter 747, a stopper 748, and a sensor 749.

The guides 741 are provided on the outer periphery of the connecting block 71, and configured to guide the vertical movement of the connecting block 71 (and the shower head 60). For example, the guides 741 each have a cylinder 741a and a shaft 741b, and a linear bush including a plurality of unillustrated rollers between the cylinder 741a and the shaft 741b can be used.

The cam follower 742 is rotatable relative to the connecting block 71 with the center axis of the cam follower 742 being connected to the side surface of the connecting block 71. The outer periphery of the cam follower 742 is formed into a regular circular shape, and the lower portion of the outer periphery is in contact with the plate cam 743. Therefore, the load of the connecting block 71 (shower head 60) is applied from the cam follower 742 to the plate cam 743, and the cam follower 742 rolls along the upper surface of the plate cam 743.

The plate cam 743 is fixed to the slider 744, and changes the vertical position (height position) of the cam follower 742 in contact with the upper surface in accordance with the movement of the slider 744. The upper surface of the plate cam 743 includes: a first step surface 743L1; a second step surface 743L2 lower than the first step surface 743L1; and an inclined surface 743I provided between the first step surface 743L1 and the second step surface 743L2. How the plate cam 743 adjusts the vertical position of the cam follower 742 will be described in detail below.

The slider 744 is disposed on the rail 745 extending in a substantially radial direction of the process chamber 11. The slider 744 includes a plurality of unillustrated rollers that are rotatable with respect to the rail 745, and slides along the extending direction of the rail 745 in response to rolling of each of the rollers.

The drive motor 746 is provided at one end of the rail 745 (the outer periphery of the process chamber 11). The drive motor 746 rotates at an appropriate speed under the control of the controller 90, and transmits a rotating force to the power transmitter 747. A servo motor, a stepping motor, or the like can be used as the drive motor 746.

The power transmitter 747 makes a connection between the drive motor 746 and the slider 744, and converts the rotating force of the drive motor 746 into the linear motion of the slider 744. No particular limitation is imposed on the configuration of the power transmitter 747, which may take, for example, a ball screw mechanism or a gear mechanism, such as a pinion, a rack, or the like. The power transmitter 747 according to the embodiment employs a ball screw mechanism.

The stopper 748 is fixed on the upper surface of the attachment board 75 and laterally of the rail 745, and projects to a height position at which the stopper 748 can interfere with the slider 744. The stopper 748 contacts the slider 744 during sliding of the slider 744, thereby defining the limit of movement of the slider 744. The position of the stopper 748 relative to the attachment board 75 is adjustable by the user.

The sensor 749 is disposed on the upper surface of the attachment board 75 and laterally of the rail 745, and is configured to detect the position of the slider 744 that is sliding on the rail 745. For example, the sensor 749 may be a transmission-type sensor configured to detect an illustrated kicker projecting from the slider 744 downward in the vertical direction. The controller 90 is configured to obtain detection information of the sensor 749, thereby identifying the position of the slider 744 and adjusting the rotation of the drive motor 746, in other words, adjusting the positions of the slider 744 and the plate cam 743.

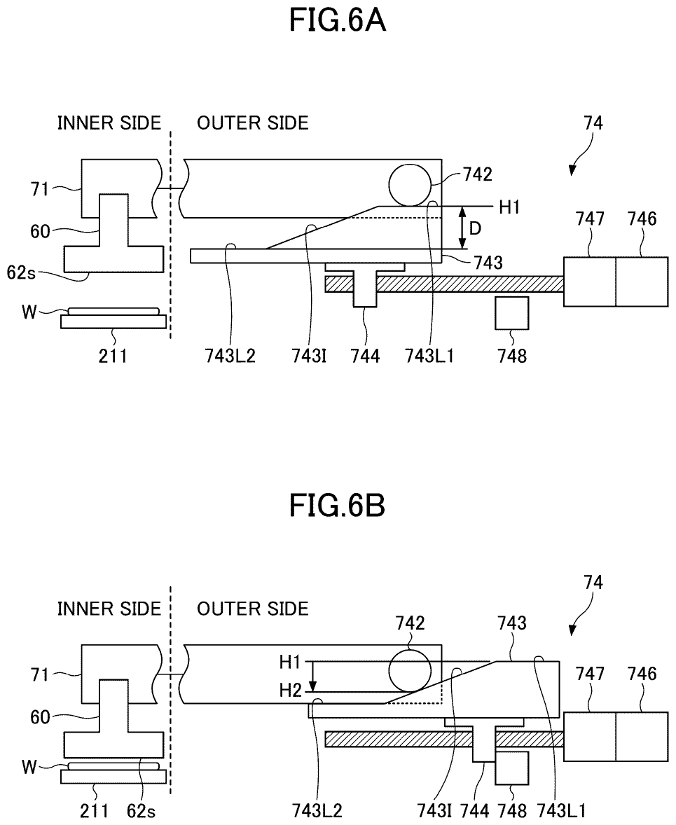

FIGS. 6A and 6B are explanatory views illustrating adjustment of the vertical position of the shower head 60 performed by the driver 74. FIG. 6A illustrates a raised position H1 of the shower head 60, and FIG. 6B illustrates a processing position H2 of the shower head 60. The driver 74 transmits a rotating force of the drive motor 746 to the power transmitter 747, thereby moving the slider 744 forward and backward. Thereby, the plate cam 743 fixed to the slider 744 moves forward and backward integrally with the slider 744.

The cam follower 742 rolls on the upper surface of the plate cam 743 as the plate cam 743 moves forward and backward. Therefore, the vertical position of the cam follower 742 is changed in accordance with the upper surface of the plate cam 743. The connecting block 71, to which the center shaft of the cam follower 742 is connected, moves upward and downward as the vertical position of the cam follower 742 changes. Thereby, the vertical position of the shower head 60 supported by the connecting block 71 is changed in the process chamber 11.

For example, a distance D between the first step surface 743L1 and the second step surface 743L2 on the upper surface of the plate cam 743 is set to 5 millimeters (mm). The inclined surface 743I is gradually inclined between the first step surface 743L1 and the second step surface 743L2, and is configured to stop the cam follower 742 at a location partway thereof.

The first step surface 743L1 of the plate cam 743 as illustrated in FIG. 6A serves as the upper limit of the vertical movement of the shower head 60. When the shower head 60 is separated from the substrate W on the stage 211, the driver 74 slides the plate cam 743 such that the cam follower 742 is located on the first step surface 743L1. Thereby, the discharge surface 62s of the shower head 60 is disposed at the raised position H1 that is sufficiently apart from the substrate W on the stage 211. For example, the discharge surface 62s of the shower head 60 is apart from the substrate W by about 4.5 mm. Therefore, even if the substrate W is warped to a great extent, possible interference of the shower head 60 with the substrate W can be avoided.

Meanwhile, when warpage of the substrate W is overcome and then the film-forming process is performed, the driver 74 slides the plate cam 743 such that the cam follower 742 is located at a location partway of the inclined surface 7431 as illustrated in FIG. 6B. The second step surface 743L2 of the plate cam 743 is the lower limit of the vertical movement of the shower head 60, and this position is set to be a position at which the discharge surface 62s of the cam follower 742 is sufficiently close to (or in contact with) the stage surface 211s without the substrate W. Therefore, when the cam follower 742 is moved to the second step surface 743L2 with the substrate W being placed on the stage 211, the shower head 60 contacts the substrate W.

The driver 74 adjusts the limit of sliding of the slider 744 using the stopper 748, and can prevent movement of the cam follower 742 to the second step surface 743L2. For example, the stopper 748 is adjusted by the user to the processing position H2 at which the distance between the discharge surface 62s of the shower head 60 and the upper surface of the substrate W becomes 1.5 mm. That is, during the film-forming process, the driver 74 slides the plate cam 743, and disposes the cam follower 742 at a location partway of the inclined surface 743I that is lowered by 3 mm with respect to the first step surface 743L1. Thereby, the substrate-processing apparatus 1 can discharge the raw material gas in a state in which the discharge surface 62s of the shower head 60 is close to the substrate W. The driver 74 can stop the cam follower 742 at the inclined surface 743I even in a state in which the plate cam 743 is not in contact with the stopper 748. Therefore, the raising and lowering mechanism 70 may dispose the shower head 60 at an appropriate position between the raised position H1 and the processing position H2.

The displacement sensor 80 as illustrated in FIG. 4 may be a laser displacement meter or the like. The displacement sensor 80 passes through a window 117 provided in the top plate 112, and is configured to detect vertical positions in the interior of the process chamber 11. In this case, a sapphire window may be used as the window 117.

The displacement sensor 80 is configured to detect the vertical position of the outer edge of the substrate W placed on the stage 211 (or the vertical position of the outer edge of the stage 211) and detect the vertical position of the lower discharger 62 of the shower head 60. In order to obtain two detected data (i.e., the upper position and the lower position), the displacement sensor 80 may be configured to move in the horizontal direction by the action of an unillustrated mover, thereby changing the position thereof. By using these two detected data, the controller 90 calculates the distance between the substrate W and the discharge surface 62s of the shower head 60. Thereby, the controller 90 can appropriately adjust the vertical position of the shower head 60 by controlling the driver 74 in accordance with the calculated distance.

As illustrated in FIG. 1, the controller 90 controls the components of the substrate-processing apparatus 1. The controller 90 includes a control body 91 and a user interface 95. The control body 91 is a computer including a processor 92, a memory 93, an unillustrated input/output interface, and an unillustrated communication interface. The processor 92 is a combination of one or more of a CPU (Central Processing Unit), a GPU (Graphics Processing Unit), an ASIC (Application Specific Integrated Circuit), an FPGA (Field-Programmable Gate Array), a circuit formed by a plurality of discrete semiconductors, and the like. The processor 92 executes one or more programs stored in the memory 93. The memory 93 includes: a main memory formed by a semiconductor memory and the like; and an auxiliary memory formed by a disk, a semiconductor memory (flash memory), and the like.

Also, the user interface 95 is connected to an input/output interface of the control body 91. No particular limitation is imposed on the user interface 95. Examples of the user interface 95 include a touch panel, a monitor, a keyboard, a mouse, and the like.

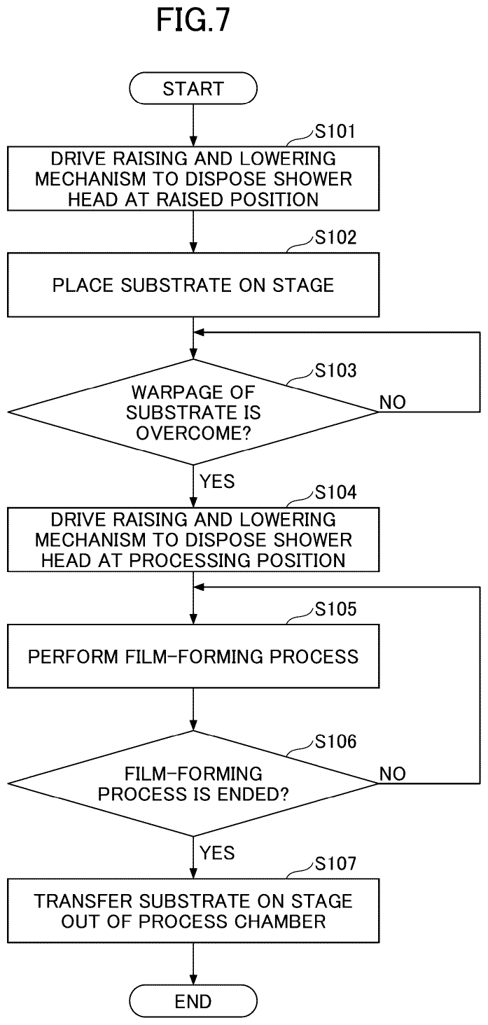

The substrate-processing apparatus 1 according to the embodiment is basically configured as described above, and how the substrate-processing apparatus 1 works (substrate-processing method) will be described below with reference to FIG. 7. FIG. 7 is a flowchart illustrating the substrate-processing method performed by the substrate-processing apparatus 1.

The controller 90 controls the components of the substrate-processing apparatus 1, thereby performing steps S101 to S107 of the substrate-processing method illustrated in FIG. 7. In the substrate-processing method, the internal temperature of the process chamber 11 is heated by the heater 15 to a high temperature.

In order for the stage 211 of the rotation table 21 to receive the substrate W, the controller 90 drives the raising and lowering mechanism 70 so as to dispose the shower head 60 at the raised position H1 as a preliminary preparation (step S101). The reason for this is as follows. Specifically, as described above, the substrate W may warp due to the local temperature rising experienced by the substrate W upon transfer thereof into the process chamber 11. If the shower head 60 is located at the processing position H2 when the rotation table 21 is rotated with the substrate W being warped, the substrate W will interfere with the shower head 60.

Specifically, the controller 90 controls the drive motor 746 of the raising and lowering mechanism 70 so as to slide the plate cam 743, thereby disposing the cam follower 742 at the first step surface 743L1 (see FIG. 6A). Thereby, the discharge surface 62s of the shower head 60 is disposed at the raised position H1 that is sufficiently apart from the substrate W placed on the stage 211.

In a state in which the shower head 60 is disposed at the raised position H1, the controller 90 places the substrate W onto the stage 211 (step S102). At this time, the controller 90 disposes the stage 211, on which the substrate W is to be placed, at a position next to the transfer port 14 of the process chamber 11. Then, the controller 90 moves the transfer device 14a through the transfer port 14, and drives the lifter 30 to raise the lift pins 31 from the stage 211 for receiving the substrate W from the transfer device 14a. After retracting the transfer device 14a, the controller 90 lowers the lift pins 31 and thus places the substrate W on the stage 211. Also, the controller 90 rotates the rotation table 21 to sequentially change the stage 211 next to the transfer port 14 and repeat the above procedure, thereby placing the substrate W on the stage 211.

At this time, because the shower head 60 is disposed at the raised position H1 as described above, even if the rotation table 21 is rotated, the substrate W on the stage 211 is prevented from interfering with the shower head 60. The reaction gas nozzle 122N and the separation gas nozzles 123N and 124N (including the projections 17) are originally located on the upper side of the processing position of the shower head 60 in the vertical direction. Thereby, these gas nozzles are prevented from contacting the substrate W on the stage 211.

When the substrate W is placed on the stage 211, the controller 90 determines whether or not the warpage of the substrate W is overcome (or sufficiently reduced) (step S103). In order to determine whether or not the warpage of the substrate W is overcome, the start of the film-forming process may be delayed for a predetermined period, or the state of the warpage of the substrate W may be monitored based on the data detected by the displacement sensor 80. While waiting for the warpage of the substrate W to be overcome, preferably, the controller 90 performs preparation for processing the substrate (e.g., adjustment of the internal pressure and temperature of the process chamber 11, and the like). When the warpage of the substrate W is overcome (step S103: YES), the controller 90 causes the flow to proceed to step S104.

In step S104, the controller 90 controls the drive motor 746 of the raising and lowering mechanism 70 to slide the plate cam 743, thereby disposing the cam follower 742 at a location partway of the inclined surface 743I and positioning the shower head 60 at the processing position H2 (see FIG. 6B). Thereby, the discharge surface 62s of the shower head 60 becomes sufficiently close to the substrate W placed on the stage 211.

After disposing the shower head 60, the controller 90 performs a film-forming process (processing of the substrate) on the substrate W (step S105). In the film-forming process, the controller 90 rotates the stage 211 about the spinning shaft 212 while rotating the rotation table 21 about the rotation shaft 23. In this state, the raw material gas supply 121 supplies the raw material gas through the raw material gas supply tube 121t, and discharges the raw material gas from the shower head 60 to the raw material gas processing region P1. Because the shower head 60 is disposed at the processing position H2 and is sufficiently close to the substrate W, the raw material gas can be uniformly and stably adsorbed on the substrate W.

The reaction gas supply 122 discharges the reaction gas from the reaction gas nozzle 122N to the reaction gas processing region P2. Further, the separation gas supplies 123 and 124 discharge the separation gas from the separation gas nozzles 123N and 124N to the separation region D. Thereby, a desired film is formed on the surface of the substrate W.

During the film-forming process, the controller 90 monitors the duration of the film-forming process set in a recipe or the like, and determines whether or not the film-forming process is ended (step S106). When the controller 90 determines that the film-forming process is ended (step S106: YES), the controller 90 stops the rotation of the rotation table 21 and stops the supply of each gas.

After completion of the film-forming process, the controller 90 transfers the substrate W on the stage 211 out of the process chamber 11 (step S107). At this time, the controller 90 disposes the stage 211 at a position next to the transfer port 14 of the process chamber 11, and raises the lift pins 31 of the lifter 30 and hence the substrate W from the stage 211. After entry of the transfer device 14a, the controller 90 lowers the lift pins 31 to deliver the substrate W to the transfer device 14a. Thereby, the transfer device 14a transfers the substrate W out of the process chamber 11. Also, the controller 90 rotates the rotation table 21 to sequentially change the stage 211 next to the transfer port 14 and repeat the above procedure, thereby transferring the substrate W out of the stage 211. Although the shower head 60 does not need to be raised when the transfer device 14a transfers the substrate W out of the process chamber 11, the shower head 60 may be raised during this transfer process in preparation for transfer of the substrate W for the next film-forming process.

As described above, the substrate-processing method can prevent interference between the shower head 60 and the substrate W by disposing the shower head 60 at the raised position H1 when the substrate W is transferred into the process chamber 11. Meanwhile, the substrate-processing method can increase accuracy of the film-forming process by disposing the shower head 60 at the processing position H2 during the film-forming process and appropriately depositing the raw material gas, discharged from the shower head 60, to the substrate W.

The substrate-processing apparatus 1 and the substrate-processing method are not limited to the above-described embodiments, and can take various modified examples. For example, the raising and lowering mechanism 70 is configured to raise and lower the shower head 60 between the raised position H1 and the processing position H2. However, this is by no means a limitation. The raising and lowering mechanism 70 may stop the shower head 60 at an appropriate vertical position. For example, when the substrate W is warped to a small extent, the controller 90 may stop at a location partway of the inclined surface 743I without raising the shower head 60 to the raised position H1.

Also, the substrate-processing apparatus 1 may adjust the vertical position of the shower head 60 in accordance with the film thickness of the substrate W during the film-forming process performed on the substrate W. For example, when the film thickness of the substrate W is small, the shower head 60 may be lowered, while when the film thickness of the substrate W is large, the shower head 60 may be raised. Alternatively, the substrate-processing apparatus 1 may monitor the warpage of the substrate W by the displacement sensor 80 during the film-forming process, and may raise the shower head 60 at the time warpage occurs.

For example, in the above embodiment, regarding the gas supply members, the raw material gas supply 121 includes the shower head 60, while the reaction gas supply 122 and the separation gas supplies 123 and 124 include the respective nozzles. The substrate-processing apparatus 1 is not limited to this, and may employ the shower head 60 for some or all of the reaction gas supply 122 and the separation gas supplies 123 and 124. In this case, the reaction gas supply 122 including the shower head 60 may include the above-described raising and lowering mechanism 70, thereby raising and lowering the shower head 60 of the reaction gas in the vertical direction. Thus, the reaction gas supply 122 can avoid interference with the warped substrate W. Also, the separation gas supplies 123 and 124 including the shower head 60 configured to discharge the separation gas may include the above-described raising and lowering mechanism 70, thereby raising and lowering the shower head 60 of the separation gas. Also, when the separation gas supplies 123 and 124 include the shower head 60, preferably, the projections 17 are also configured to be raised and lowered integrally with the shower head 60. Thereby, the separation gas supplies 123 and 124 can avoid interference with the warped substrate W, and the lower surface of the projections 17 can become closer to the substrate W on the stage 211.

Alternatively, the substrate-processing apparatus 1 may employ a nozzle configured to supply the raw material gas as the supply member of the raw material gas supply 121. Even if the nozzle is employed, the substrate-processing apparatus 1 can include a raising and lowering mechanism configured to raise and lower the nozzle. That is, the raising and lowering mechanism raises the nozzle, thereby avoiding interference between the warped substrate W and the nozzle, while the raising and lowering mechanism makes the nozzle close to the substrate W during processing of the substrate, thereby increasing accuracy of the processing of the substrate. Therefore, the substrate-processing apparatus 1 according to the embodiment as illustrated in FIG. 1 may be configured to raise and lower the nozzles of the reaction gas supply 122 and the separation gas supplies 123 and 124 each employing the nozzle. By raising the nozzles, interference between the warped substrate W and the nozzles is avoided. Also, by making the nozzles close to the substrate W during the processing of the substrate, the accuracy of the processing of the substrate can be increased.

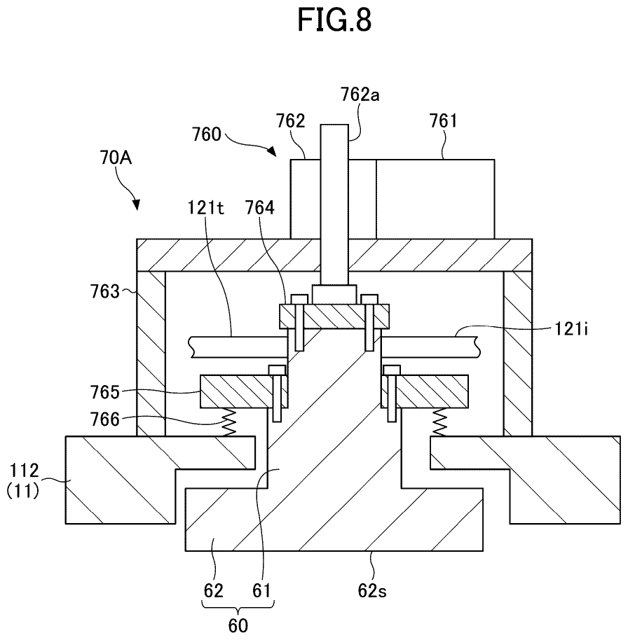

FIG. 8 is a cross-sectional side view illustrating a raising and lowering mechanism 70A according to a first modified example. The raising and lowering mechanism 70A according to the first modified example as illustrated in FIG. 8 is different from the above-described raising and lowering mechanism 70 in that the raising and lowering mechanism 70A includes a driver 760 configured to transmit a rotating force of a drive motor 761 to a power transmitter 762, thereby raising and lowering a support shaft 762a of the power transmitter 762 in the vertical direction. In addition to the drive motor 761 and the power transmitter 762, the raising and lowering mechanism 70A includes a support frame 763, a first connecting block 764, a second connecting block 765, a bellows 766, and the like.

The support frame 763 includes: an unillustrated projecting frame that projects from the upper surface of the top plate 112 upward in the vertical direction; and an unillustrated bridging frame that bridges the upper ends of the projecting frame. The support frame 763 is configured to support the drive motor 761 and the power transmitter 762 in the bridging frame.

The drive motor 761 is configured to rotate at an appropriate speed under the control of the controller 90, and transmit a rotating force to the power transmitter 762. A servo motor, a stepping motor, or the like can be used as the drive motor 761.

The power transmitter 762 is configured to convert the rotating force of the drive motor 761 to a linear motion of the support shaft 762a, and raise and lower the support shaft 762a in the vertical direction. The first connecting block 764 is connected to the lower end of the support shaft 762a.

The first connecting block 764 is connected to the upper end of the upper connector 61 of the shower head 60 with a fastener, such as a screw or the like. The second connecting block 765 is connected to the intermediate position of the upper connector 61 with a fastener, such as a screw or the like. The bellows 766 is provided between the second connecting block 765 and the top plate 112, and closes the internal space of the process chamber 11 while enabling the shower head 60 to be raised and lowered.

The raw material gas supply tube 121t and the inert gas supply tube 121i are connected to the upper connector 61 between the first connecting block 764 and the second connecting block 765.

The raising and lowering mechanism 70A configured in this manner can raise and lower the shower head 60 in the vertical direction, and can function and work in the same manner as in the raising and lowering mechanism 70. In particular, the raising and lowering mechanism 70A has a simple structure that is raised and lowered by a rotating force of the drive motor 761, and the raising and lowering mechanism 70 can be reduced in weight to smoothly raise and lower the shower head 60.

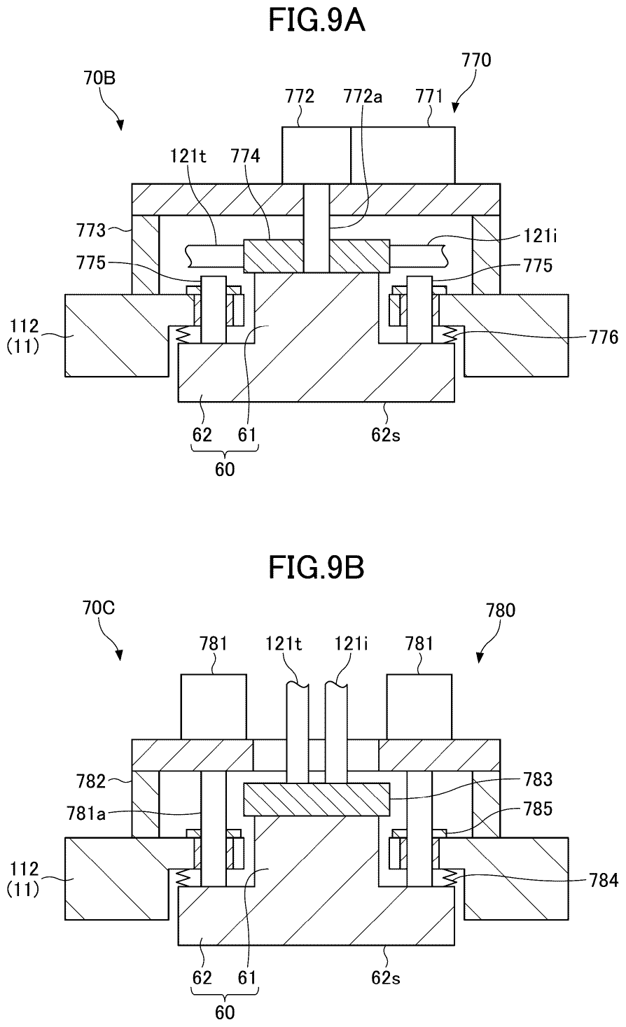

FIG. 9A is a cross-sectional side view illustrating a raising and lowering mechanism 70B according to a second modified example. FIG. 9B is a cross-sectional side view illustrating a raising and lowering mechanism 70C according to a third modified example. The raising and lowering mechanism 70B according to the second modified example as illustrated in FIG. 9A is different from the above-described raising and lowering mechanisms 70 and 70A in that the raising and lowering mechanism 70B includes a driver 770 including a plurality of guides 775 configured to guide the vertical movement of the lower discharger 62 of the shower head 60.

Specifically, similar to the raising and lowering mechanism 70A, the raising and lowering mechanism 70B includes a drive motor 771, a power transmitter 772 including a support shaft 772a, and a support frame 773, and also supports the upper end of the shower head 60 by a connecting block 774 connected to the support shaft 772a. The raw material gas supply tube 121t and the inert gas supply tube 121i are connected to the connecting block 774 and the like.

A plurality of guides 775 are provided to penetrate the top plate 112 laterally of the upper connector 61 of the shower head 60. The guides 775 are provided at intervals along the circumferential direction of the top plate 112. A linear bush or the like is applicable as each of the guides 775, and guides the raising and lowering of the shower head 60.

A bellows 776 configured to close the space of the process chamber 11 is provided outward of the guide 775 in the radial direction. The bellows 776 is joined to the lower surface of the top plate 112 and to the upper surface of the lower discharger 62.

The raising and lowering mechanism 70B configured in this manner can raise and lower the shower head 60 in the vertical direction, and can function and work in the same manner as in the above-described raising and lowering mechanisms 70 and 70A. In particular, the raising and lowering mechanism 70B can more stably raise and lower the shower head 60 by the guides 775.

The raising and lowering mechanism 70C according to the third modified example as illustrated in FIG. 9B is different from the above-described raising and lowering mechanisms 70, 70A, and 70B in that the raising and lowering mechanism 70C includes a driver 780 including a plurality of (two in the illustrated example) drive sources 781 configured to raise and lower the shower head 60. A cylinder mechanism (hydraulic pressure, pneumatic pressure, or the like) is applied to the drive sources 781 in the present modified example. However, this is by no means a limitation. A motor or a power transmitter may be applied to the drive sources 781.

The drive sources 781 are supported by a support frame 782 such that movable shafts 781a thereof project downward in the vertical direction. The lower ends of the movable shafts 781a are connected to the lower discharger 62 of the shower head 60, thereby raising and lowering the shower head 60.

The raising and lowering mechanism 70C includes a connecting block 783 connected to the upper connector 61, a bellows 784 configured to close the process chamber 11, a guide 785 configured to guide the movable shaft 781a, and the like.

The raising and lowering mechanism 70C configured as described above can raise and lower the shower head 60 in the vertical direction, and can function and work in the same manner as in the above-described raising and lowering mechanisms 70, 70A, and 70B. In particular, by including the drive sources 781, the raising and lowering mechanism 70C can disperse the load applied to the raising and lowering of the shower head 60, and perform the raising and lowering more stably.

The raising and lowering mechanism 70 may employ various other drivers. For example, the raising and lowering mechanism 70 may employ a configuration using a double-shaft motor or a worm gear, a toggle mechanism (link mechanism) combining a plurality of links, or the like.

The technical ideas and effects of the present disclosure described in the above embodiments will be described below.

In a first aspect of the present disclosure, the substrate-processing apparatus 1 includes: the process chamber 11 configured to process the plurality of substrates W; the rotation table 21 that is disposed in the process chamber 11 so as to be rotatable and at which the substrates W are to be placed at positions that are away in the radial direction of the rotation table 21 from the center of rotation of the rotation table 21; the supply member (shower head 60) configured to supply gas to the substrates W placed on the rotation table 21; and the raising and lowering mechanism 70 configured to raise and lower the supply member relative to the process chamber 11.

According to the above, the substrate-processing apparatus 1 can avoid interference between the supply member (shower head 60) and the substrate W by raising and lowering the supply member by the raising and lowering mechanism 70. In particular, the substrate W may be warped, and thus by raising the supply member by the raising and lowering mechanism 70, interference with the warped substrate W can be successfully avoided. When the warpage of the substrate W becomes small, the substrate-processing apparatus 1 can accurately process the substrate by lowering the supply member by the raising and lowering mechanism 70.

Also, the substrate-processing apparatus 1 includes the controller 90 configured to control the raising and lowering mechanism 70. The controller 90 is configured to dispose the supply member (shower head 60) at the raised position H1 that is higher than the processing position H2 at which the supply member is to be disposed upon processing the substrate W, before the substrate W is transferred onto the rotation table 21 from the exterior of the process chamber 11. Thereby, even if the substrate W is warped upon transfer of the substrate W, the substrate-processing apparatus 1 can reliably avoid interference between the supply member and the substrate W by positioning the supply member at the raised position H1.

Also, the controller 90 lowers the supply member (shower head 60) from the raised position H1 to the processing position H2 in response to reduction in the warpage of the substrates W placed on the rotation table 21. Thereby, the substrate-processing apparatus 1 can dispose the supply member at an appropriate position while preventing contact between the supply member and the substrate W.

Also, the controller 90 lowers the supply member (shower head 60) from the raised position H1 to the processing position H2, and then supplies gas from the supply member to process the substrates W while rotating the rotation table 21. Thereby, the substrate-processing apparatus 1 can stably process the substrates W.

The supply member is the shower head 60 including the discharge surface 62s parallel to the rotation table 21 and discharging gas from the discharge surface 62s. Thereby, the substrate-processing apparatus 1 can uniformly supply gas from the discharge surface 62s to the surface of the substrate W.

Also, the shower head 60 includes the lower discharger 62 configured to discharge gas and the upper connector 61 configured to make a connection between the raising and lowering mechanism 70 and the lower discharger 62. The lower discharger 62 diffuses the gas flowing via the upper connector 61 in the horizontal direction in the interior of the process chamber 11. Thereby, the substrate-processing apparatus 1 can more stably and uniformly supply gas from the exterior of the process chamber 11 to the substrates W of the rotation table 21.

The raising and lowering mechanism 70 includes the connecting block 71 configured to support the upper end of the shower head 60 externally of the process chamber 11. The area of the connecting block 71 in a plan view is smaller than the area of the lower discharger 62 in a plan view. Thereby, the atmospheric pressure applied to the connecting block 71 externally of the process chamber 11 is reduced, and the load applied upon the vertical movement of the raising and lowering mechanism 70 can be reduced.

The supply member (shower head 60) is configured to supply the raw material gas to be adsorbed on the substrate W in the interior of the process chamber 11. By raising and lowering the supply member configured to supply the raw material gas to the substrate W, the substrate-processing apparatus 1 can supply the raw material gas in a state in which the supply member is sufficiently close to the substrate W during the processing of the substrate.

The supply member (shower head 60) is configured to supply the reaction gas that reacts with the raw material gas adsorbed on the substrate W in the interior of the process chamber 11. By raising and lowering the supply member configured to supply the reaction gas to the substrate W, the substrate-processing apparatus 1 can supply the reaction gas in a state in which the supply member is sufficiently close to the substrate W during the processing of the substrate.

The supply member (shower head 60) is configured to supply the separation gas that separates the raw material gas and the reaction gas supplied to the substrate W in the interior of the process chamber 11. By raising and lowering the supply member configured to supply the separation gas to the substrate W, the substrate-processing apparatus 1 can reduce the space of the separation gas supplied by the supply member during the processing of the substrate, and further promote the separation between the raw material gas and the reaction gas.

The rotation table 21 includes the stages 211 on which the substrates W are to be placed. The stages 211 rotate the placed substrates W about the center of each of the stages 211 separately from the rotation of the rotation table 21. Thereby, the substrate-processing apparatus 1 can further promote uniformity of the processing of the substrate with respect to the substrate W. In addition, even if the structure on the rotation table 21 side becomes heavier, the substrate-processing apparatus 1 can reduce the load applied upon the vertical movement because the structure on the supply member (shower head 60) side is raised and lowered.

In a second aspect of the present disclosure, a substrate-processing method performed by the substrate-processing apparatus 1, which includes the process chamber 11 configured to process the plurality of substrates W; the rotation table 21 that is disposed in the process chamber 11 so as to be rotatable and at which the substrates W are to be placed at positions that are away in the radial direction of the rotation table 21 from the center of rotation of the rotation table 21; the supply member (shower head 60) configured to supply gas to the substrates W placed on the rotation table 21; and the raising and lowering mechanism 70 configured to raise and lower the supply member relative to the process chamber 11, includes: disposing the supply member at the raised position H1 that is higher than the processing position H2 at which the supply member is to be disposed upon processing the substrate W, before the substrate W is transferred onto the rotation table 21 from the exterior of the process chamber 11. In this case, the substrate-processing method can avoid interference between the supply member and the substrate W in the process chamber 11, and can perform the processing of the substrate with high accuracy.

The substrate-processing apparatus 1 and the substrate-processing method according to the embodiments disclosed herein are illustrative in all respects and not restrictive. The embodiments may be modified and improved in various forms without departing from the scope and the subject of the claims recited. The matters described in the above embodiments can take other configurations to the extent that there is no contradiction, and can be combined together to the extent that there is no contradiction.

According to one aspect, it is possible to avoid interference between the substrate and the supply member configured to supply gas, and perform the processing of the substrate with high accuracy.

What is claimed is:

1. A substrate-processing apparatus, comprising:
a process chamber configured to process a plurality of substrates;
a rotation table that is disposed in an interior of the process chamber so as to be rotatable and at which the substrates are to be placed at positions that are away in a radial direction of the rotation table from a center of rotation of the rotation table;
a supply member configured to supply gas to the substrates placed on the rotation table; and
a raising and lowering mechanism configured to raise and lower the supply member relative to the rotation table.

2. The substrate-processing apparatus according to claim 1, further comprising:
a controller configured to control the raising and lowering mechanism, and including a processor and a memory storing one or more programs, which when executed, cause the processor to:
dispose the supply member at a raised position that is higher than a processing position at which the supply member is to be disposed upon processing the substrates, before the substrates are transferred onto the rotation table from an exterior of the process chamber.

3. The substrate-processing apparatus according to claim 2, wherein
the one or more programs, when executed, cause the processor to:
lower the supply member from the raised position to the processing position in response to reduction in warpage of the substrates placed on the rotation table.

4. The substrate-processing apparatus according to claim 3, wherein
the one or more programs, when executed, cause the processor to:
lower the supply member from the raised position to the processing position, and then supply the gas from the supply member to process the substrates while rotating the rotation table.

5. The substrate-processing apparatus according to claim 1, wherein
the supply member is a shower head that includes a discharge surface parallel to the rotation table and is configured to discharge the gas from the discharge surface.

6. The substrate-processing apparatus according to claim 5, wherein
the shower head includes
a lower discharger configured to discharge the gas, and
an upper connector configured to make a connection between: the raising and lowering mechanism; and the lower discharger, and
the lower discharger includes a gas diffusion chamber, and diffuses the gas flowing via the upper connector in a horizontal direction in an interior of the gas diffusion chamber.

7. The substrate-processing apparatus according to claim 6, wherein
the raising and lowering mechanism includes
a connecting block configured to support an upper end of the shower head externally of the process chamber,
an area of the connecting block in a plan view is smaller than an area of the lower discharger in a plan view.

8. The substrate-processing apparatus according to claim 1, wherein
the supply member is configured to supply a raw material gas to be adsorbed on the substrates in the interior of the process chamber.

9. The substrate-processing apparatus according to claim 1, wherein
the supply member is configured to supply a reaction gas that reacts with a raw material gas adsorbed on the substrates in the interior of the process chamber.

10. The substrate-processing apparatus according to claim 1, wherein
the supply member is configured to supply a separation gas that separates the raw material gas and the reaction gas supplied to the substrate in the interior of the process chamber.

11. The substrate-processing apparatus according to claim 1, wherein
the rotation table includes
a plurality of stages on which the substrates are to be placed, and
a stage of the stages on which a substrate of the substrates is placed rotates the substrate about a center of the stage separately from the rotation of the rotation table.

12. A substrate-processing method performed by a substrate-processing apparatus that includes a process chamber configured to process a plurality of substrates; a rotation table that is disposed in an interior of the process chamber so as to be rotatable and at which the substrates are to be placed at positions that are away in a radial direction of the rotation table from a center of rotation of the rotation table; a supply member configured to supply gas to the substrates placed on the rotation table; and a raising and lowering mechanism configured to raise and lower the supply member relative to the rotation table, the substrate-processing method comprising:
disposing the supply member at a raised position that is higher than a processing position at which the supply member is to be disposed upon processing the substrates, before the substrates are transferred onto the rotation table from an exterior of the process chamber.
